(19) United States
(12) Patent Application Publication
(10) Pub. No.: US 2023/0387661 A1
(43) Pub. Date: Nov. 30, 2023

(54) LASER DEVICE

(71) Applicant: Shphotonics Ltd, Suzhou (CN)

(72) Inventors: Lei SUN, Suzhou (CN); Bing QIU, Suzhou (CN)

(21) Appl. No.: 18/321,122

(22) Filed: May 22, 2023

(30) Foreign Application Priority Data
May 25, 2022 (CN) 202210581238.2

(51) Int. Cl. H01S 5/187

(52) U.S. Cl. CPC H01S 5/187

(57) ABSTRACT

A laser device includes a laser device body and a light-emission assembly. The light-emission assembly is arranged at one end of the laser device body and includes an optical processing assembly. The optical processing assembly includes a first reflection layer, a gain medium layer, and a second reflection layer arranged in sequence. At least two metasurface devices are arranged in at least one of the first reflection layer and the second reflection layer. The at least two metasurface devices are configured to reflect or refract to-be-emitted light to cause the to-be-emitted light to be transmitted and modulated through the gain medium layer.

### CROSS-REFERENCE TO RELATED APPLICATION

This application claims priority to Chinese Application No. 202210581238.2, filed on May 25, 2022, the entire content of which is incorporated herein by reference.

### TECHNICAL FIELD

The present disclosure relates to the optical technology field and, in particular, to a laser device.

### BACKGROUND

An currently existing laser device typically includes a laser device body and an optical processing assembly. The optical processing assembly is configured to emit a laser beam, which is typically a point emitting device. The laser exists within an area covered by a reflection mirror of the optical processing assembly. An output spot is similar in shape to a reflective mirror surface.

To increase the output power of a laser device, the volume of a gain medium in the optical processing assembly needs to be enlarged. One way to enlarge the volume of the gain medium is to increase the length of the optical processing assembly, which results in changes of the wavelength and mode of emitted light. Another way to enlarge the volume of the gain medium is to increase the number of reflection mirrors and the size of light-emitting aperture. The enlarged aperture causes the light from different light-emitting apertures to become incoherent and the laser device becomes an area emitting device, which does not meet the point emitting requirement in certain scenarios.

Therefore, the problem of increasing the light-emitting power through the laser device while satisfying the requirement of point emitting needs to be solved.

### SUMMARY

Embodiments of the present disclosure provide a laser device, including a laser device body and a light-emission assembly. The light-emission assembly is arranged at one end of the laser device body and includes an optical processing assembly. The optical processing assembly includes a first reflection layer, a gain medium layer, and a second reflection layer arranged in sequence. At least two metasurface devices are arranged in at least one of the first reflection layer and the second reflection layer. At least two metasurface devices are configured to reflect or refract to-be-emitted light to cause the to-be-emitted light to be transmitted and modulated through the gain medium layer.

### BRIEF DESCRIPTION OF THE DRAWINGS

FIG. 1 is a schematic diagram of an optical processing assembly according to some embodiments of the present disclosure.

FIG. 2 is a schematic diagram of another optical processing assembly according to some embodiments of the present disclosure.

FIG. 3 is a schematic diagram of another optical processing assembly according to some embodiments of the present disclosure.

FIG. 4 is a schematic diagram of another optical processing assembly according to some embodiments of the present disclosure.

FIG. 5 is a schematic diagram showing an optical path of an optical processing assembly according to some embodiments of the present disclosure.

### REFERENCE NUMERALS

| | |
|---|---|
| 1 Light-emission assembly | 2 Optical processing assembly |
| 11 First metal electrode layer | 12 First reflection layer |
| 13 Gain medium layer | 14 Second reflection layer |
| 15 Second metal electrode layer | 16 Isolation layer |
| 17 Substrate layer | 21 First metasurface device |

### DETAILED DESCRIPTION OF THE EMBODIMENTS

In the following, some example embodiments are described. As those skilled in the art would recognize, the described embodiments can be modified in various manners, all without departing from the spirit or scope of the present disclosure. Accordingly, the drawings and descriptions are illustrative in nature and not limiting.

In the present disclosure, terms such as “first,” “second,” and “third” can be used to describe various elements, components, regions, layers, and/or parts. However, these elements, components, regions, layers, and/or parts should not be limited by these terms. These terms are only used to distinguish one element, component, region, layer, or part from another element, component, region, layer, or layer. Therefore, a first element, component, region, layer, or part discussed below can also be referred to as a second element, component, region, layer, or part, which does not constitute a departure from the teachings of the present disclosure.

A term specifying a relative spatial relationship, such as “below,” “beneath,” “lower,” “under,” “above,” or “higher,” can be used in the disclosure to describe the relationship of one or more elements or features relative to other one or more elements or features as illustrated in the drawings. These relative spatial terms are intended to also encompass different orientations of the device in use or operation in addition to the orientation shown in the drawings. For example, if the device in a drawing is turned over, an element described as “beneath,” “below,” or “under” another element or feature would then be “above” the other element or feature. Therefore, an example term such as “beneath” or “under” can encompass both above and below. Further, a term such as “before,” “in front of,” “after,” or “subsequently” can similarly be used, for example, to indicate the order in which light passes through the elements. A device can be oriented otherwise (e.g., being rotated by 90 degrees or being at another orientation) while the relative spatial terms used herein still apply. In addition, when a layer is referred to as being “between” two layers, it can be the only layer between the two layers, or there can be one or more intervening layers. In this disclosure, if a light beam encounters a first element and then reaches a second element, the second element is referred to as being downstream the first element or downstream the first element in an optical path, and correspondingly the first element is referred to as being upstream the second element or upstream the second element in the optical path.

Terminology used in the disclosure is for the purpose of describing the embodiments only and is not intended to limit the present disclosure. As used herein, the terms “a,” “an,” and “the” in the singular form are intended to also include the plural form, unless the context clearly indicates otherwise. Terms such as “comprising” and/or “including” specify the presence of stated features, entities, steps, operations, elements, and/or parts, but do not exclude the existence or addition of one or more other features, integers, steps, operations, elements, parts, and/or combinations thereof. As used herein, the term “and/or” includes any and all combinations of one or more of the listed items. The phrases “at least one of A and B” and “at least one of A or B” mean only A, only B, or both A and B.

When an element or layer is referred to as being “on,” “connected to,” “coupled to,” or “adjacent to” another element or layer, the element or layer can be directly on, directly connected to, directly coupled to, or directly adjacent to the other element or layer, or there can be one or more intervening elements or layers. In contrast, when an element or layer is referred to as being “directly on,” “directly connected to,” “directly coupled to,” or “directly adjacent to” another element or layer, then there is no intervening element or layer. “On” or “directly on” should not be interpreted as requiring that one layer completely covers the underlying layer.

In the disclosure, description is made with reference to schematic illustrations of example embodiments (and intermediate structures). As such, changes of the illustrated shapes, for example, as a result of manufacturing techniques and/or tolerances, can be expected. Thus, embodiments of the present disclosure should not be interpreted as being limited to the specific shapes of regions illustrated in the drawings, but are to include deviations in shapes that result, for example, from manufacturing. Therefore, the regions illustrated in the drawings are schematic and their shapes are not intended to illustrate the actual shapes of the regions of the device and are not intended to limit the scope of the present disclosure.

Unless otherwise defined, all terms (including technical and scientific terms) used herein have the same meaning as commonly understood by those of ordinary skill in the art to which this disclosure belongs. Terms such as those defined in commonly used dictionaries should be interpreted to have meanings consistent with their meanings in the relevant field and/or in the context of this disclosure, unless expressly defined otherwise herein.

As used herein, the term “substrate” can refer to the substrate of a diced wafer, or the substrate of an un-diced wafer. Similarly, the terms “chip” and “die” can be used interchangeably, unless such interchange would cause conflict. The term “layer” can include a thin film, and should not be interpreted to indicate a vertical or horizontal thickness, unless otherwise specified.

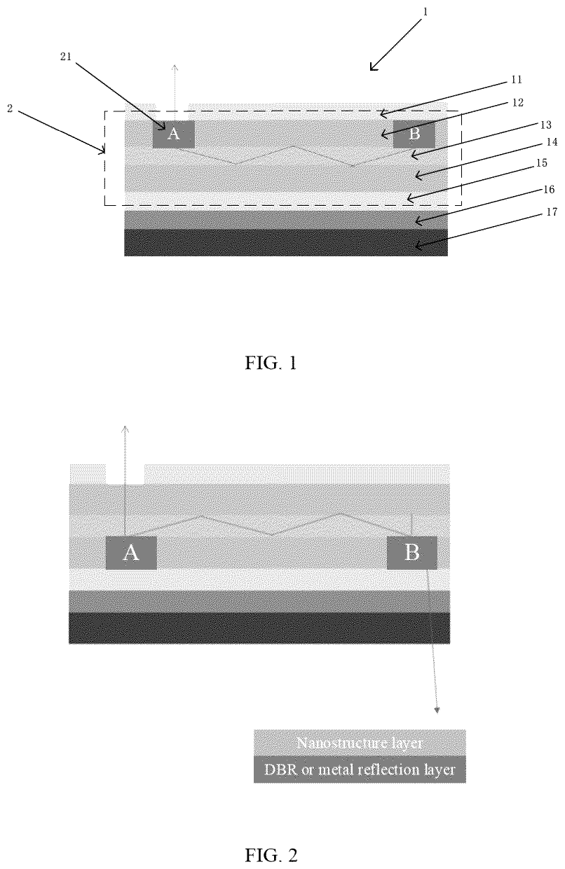

FIGS. 1 to 4 are schematic diagrams of optical processing assemblies 2 of four laser devices according to some embodiments of the present disclosure. As shown in FIGS. 1 to 4, a laser device includes a laser device body and a light-emission assembly 1 disposed at an end of the laser device body.

The light-emission assembly 1 includes an optical processing assembly 2. The optical processing assembly 2 includes a first reflection layer 12, a gain medium layer 13, and a second reflection layer 14 arranged in sequence.

The at least one of the first reflection layer 12 and the second reflection layer 14 includes at least two metasurface devices.

The at least two metasurface devices can be configured to reflect or refract to modulate to-be-emitted light. Thus, the to-be-emitted light can be transmitted and modulated through the gain medium layer 13.

In some embodiments, the laser device includes the laser device body and the light-emission assembly 1 arranged at one end of the laser device body. The light-emission assembly 1 includes the optical processing assembly 2. The optical processing assembly 2 includes the first reflection layer 12, the gain medium layer 13, and the second reflection layer 14 arranged in sequence. At least one of the first reflection layer 12 and the second reflection layer 14 can include at least two metasurface devices. The two metasurface devices can be configured to reflect or refract to module the to-be-emitted light. Thus, the to-be-emitted light can be transmitted and modulated through the gain medium layer 13 to increase light-emitting power while maintaining single-point light emission.

In some embodiments of the present disclosure, the optical processing assembly 2 further includes a first metal electrode layer 11, a second metal electrode layer 15, an isolation layer 16, and a substrate layer 17.

The first metal electrode layer 11 is arranged at a first end of the light-emission assembly 1.

The second metal electrode layer 15 is arranged at a second end of the light-emission assembly 1.

The isolation layer 16 is arranged at a second end of the second metal electrode layer 15.

The substrate layer 17 is arranged at a second end of the isolation layer 16.

In some embodiments, the optical processing assembly 2 includes the first metal electrode layer 11, the first reflection layer 12, the gain medium layer 13, the second reflection layer 14, the second metal electrode layer 15, the isolation layer 16, and the substrate layer 17 arranged in sequence. The isolation layer 16 and the substrate layer 17 can be thermally conductive. The substrate layer 17 can be made of a metal material.

In some other embodiments of the present disclosure, the optical processing assembly 2 further includes a light-emission opening structure arranged on a first side of the first metal electrode layer 11.

In some embodiments, one or more light-emission opening structures can be arranged in the first metal electrode layer 11, which is not limited here.

In some other embodiments of the present disclosure, each one of the at least two metasurface devices can be one of a semi-transparent and semi-reflective (also referred to as “transflective”) metasurface device, a reflective metasurface device, and a transmissive metasurface device.

In some embodiments, metasurface device can refer to a device formed by arranging artificial two-dimensional structures having a subwavelength size. In an UV-visible and near infrared optical waveband, a basic structural unit of the metasurface device can be a nanostructure unit with a size in the order of nanometers. Metasurface can realize flexible and effective control of the characteristics, such as propagation direction, polarization mode, amplitude, and phase, of electromagnetic waves. Metasurface can also have ultra-light and ultra-thin characteristics. A metasurface optical device made based on the metasurface can have excellent optical performance, small volume, and high level of integration compared to a conventional refractive optical device. Thus, the metasurface optical device can be applied in a portable and miniaturized device such as an augmented reality wearable apparatus, a virtual reality wearable apparatus, and a mobile terminal lens.

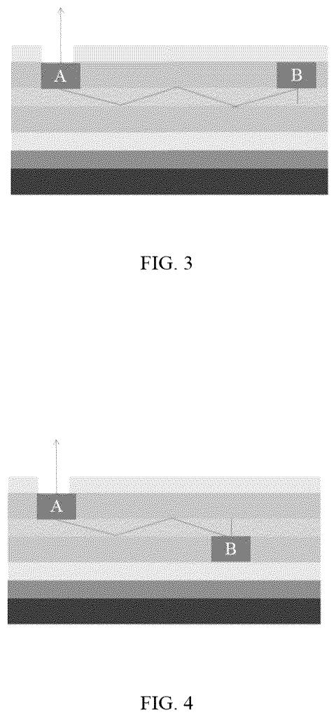

A metasurface device can be a semi-transparent and semi-reflective type metasurface device, a reflective type metasurface device, or a transmissive type metasurface device. For example, as shown in FIG. 1, FIG. 3, or FIG. 4, a metasurface device under the light-emission opening structures is the semi-transparent and semi-reflective type metasurface device. As shown in FIG. 2, the metasurface device under the light-emission opening structure is the reflective type metasurface device. The two metasurface devices can deflect the light.

In some embodiments, a pump source can provide pump energy for the laser device. Population inversion and light-emission amplification can be realized through a gain medium of the gain medium layer. A cavity reflection mirror can be configured to resonate a certain wavelength or a mode field to emit light. Thus, in the conventional laser device, since light can be transmitted in a straight line in a same and uniform medium, the conventional laser device can only cause the light to pass through a gain medium with a fixed volume. In contrast, in the laser device consistent with the disclosure, metasurface devices with a light deflection function are added to two sides of the gain medium layers, the light can be refracted and/or reflected multiple times in the gain medium layer with the fixed volume. Thus, the effective volume of the gain medium can be increased, and the population inversion and the light amplification can be continuously implemented to effectively provide the power of the laser device. In some embodiments, the metasurface device can be replaced by another reflection structure, for example, a distributed Bragg reflector (DBR), a metal reflection layer, or a nanometer layer, which is not limited.

As shown in FIGS. 1 to 4, the population inversion and light amplification are implemented through the gain medium.

In some embodiments, as shown in FIG. 1, two metasurface devices are arranged in the first reflection layer of the optical processing assembly. A first metasurface device (metasurface device A) is arranged under the light-emission opening structure and is a semi-transparent and semi-reflective type metasurface device. A second metasurface device (metasurface device B) can be arranged at another position and be a reflective type metasurface device.

In some embodiments, as shown in FIG. 2, the two metasurface devices are arranged in the second reflection layer in the optical processing assembly. The first metasurface device is arranged under the light-emission opening structure and is a reflective type metasurface device. The second metasurface device is arranged at another position and can also be a reflective type metasurface device.

In some embodiments, as shown in FIG. 3, the two metasurface devices are arranged at the first reflection layer in the optical processing assembly. The first metasurface device is arranged under the light-emission opening structure and is a semi-transparent and semi-reflective type metasurface device. The second metasurface device is arranged at another position and can be a reflective type metasurface device.

In some embodiments, as shown in FIG. 4, one metasurface device is arranged at the first reflection layer, and one metasurface device is arranged at the second reflection layer in the optical processing assembly. The first metasurface device is arranged under the light-emission opening structure and is a semi-transparent and semi-reflective type metasurface device. The second metasurface device is arranged at another position and can be a reflective type metasurface device.

In embodiments of the present disclosure, the two metasurface devices and the two reflection layers can provide a gain optical path. Light can propagate back and forth between the two metasurface devices in a direction of the optical path shown in the figure. The light can be refracted and emitted at the first metasurface device. A direction of reflection or refraction of light can be controlled by a metasurface device, which makes it possible to form the optical path above. Because the light passes through the gain medium layer transversely, the light can pass through more particles at high energy level. Compared to the conventional laser device, in which light propagates along the direction perpendicular to the gain medium layer, the laser device consistent with the disclosure can have a larger effective volume of the gain medium, and hence the power of the laser device can be increased.

In embodiments of the present disclosure, not only the reflection and/or refraction can be achieved through the metasurface, but also another reflection material can be added to the reflection layer. Further, the reflection of the light is also not limited to the reflection path shown in the accompanying drawings. For example, the reflection paths of the light shown in FIGS. 1 to 4 include not only refraction paths indicated by the directions of the arrows but also a path in which the light returns along the original path after encountering a certain reflection material, which is not limited here.

In some other embodiments of the present disclosure, the light-emission assembly 1 further includes a first metasurface device 21 arranged on a first side of at least one of the first reflection layer 12 and the second reflection layer 14 corresponding to the light-emission opening structure.

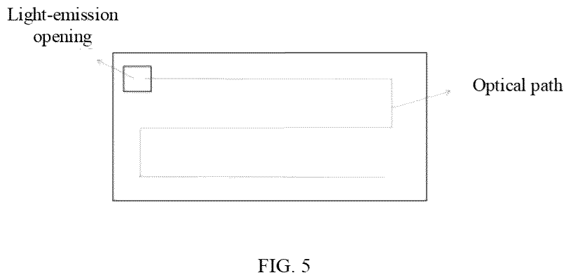

As shown in FIG. 5, in some embodiments, each light-emission opening structure corresponds to at least one metasurface device. An internal propagation path of light is shown in FIG. 5. The light can pass through the gain medium as much as possible. Then, a distance traveled by the light inside the cavity can become longer, which equivalently increases the effective volume of the gain medium and the power of the laser device. A light propagation direction can be regular or irregular. When the light reaches the light-emission opening structure, a second metasurface device can be arranged outside the light-emission opening structure to modulate deflection, shape, phase, convergence, collimation, and polarization of a light-emitting beam.

In some other embodiments of the present disclosure, a first surface of the semi-transparent and semi-reflective metasurface device can include a distributed Bragg reflector. A second surface of the semi-transparent and semi-reflective metasurface device can include a nanostructure.

In some embodiments, when the semi-transparent and semi-reflective type metasurface device is arranged above the light-emission opening structure, the first surface can be a DBR; and when the semi-transparent and semi-reflective type metasurface device is arranged above the light-emission opening structure, the first surface can be a DBR or a metal reflection surface, which is not so limited. Thus, functions such as deflection, reflection, transmission, convergence, and polarization selection of the light can be realized.

In some other embodiments of the present disclosure, the first metal electrode layer 11 further includes the first metasurface device 21. If the first metasurface device 21 is arranged at the first reflection layer 12, the first metasurface device 21 can be a semi-transparent and semi-reflective type metasurface device. If the first metasurface device 21 is arranged at the second reflection layer 14, the first metasurface device 21 can be a reflective type metasurface device.

In some embodiments, a light beam travels inclinedly. If the light beam travels in the direction perpendicular to the surface, wavelength selection can be impacted. A phase compensation layer can be added, or the position of the metasurface device can be adjusted.

In embodiments of the present disclosure, the laser device includes the laser device body and the light-emission assembly 1 arranged at one end of the laser device body. The light-emission assembly 1 includes the optical processing assembly 2. The optical processing assembly 2 includes the first reflection layer 12, the gain medium layer 13, and the second reflection layer 14 arranged in sequence. At least two metasurface devices are arranged in at least one of the first reflection layer 12 or the second reflection layer 14. The at least two metasurface devices can be configured to reflect or refract to modulate the to-be-emitted light. Thus, the to-be-emitted light can be transmitted and modulated through the gain medium layer 13 to enlarge the effective volume of the gain medium. Therefore, the light-emitting power can be increased while still satisfying the requirement of the single point light-emitting.

Details are described in the specification of the present disclosure. However, embodiments of the present disclosure can be implemented without these details. In some embodiments, well-known methods, structures, and techniques are not described in detail to avoid obscuring the understanding of the present disclosure.

Similarly, to simplify embodiments of the present disclosure and to aid in understanding one or more aspects of the present disclosure, various features of embodiments of the present disclosure can be grouped together in a single embodiment, figure, or description in the description of exemplary embodiments of the present disclosure.

In addition, those skilled in the art can understand that although some embodiments can include certain features included in other embodiments and not other features, combinations of features of different embodiments are within the scope of the present disclosure and form different embodiments.

Embodiments are used to illustrate and limit the present disclosure. The term “one” or “a” before an element does not exclude the presence of a plurality of elements. The terms “first,” “second,” and “third” does not imply any particular order. The terms can be interpreted as names. The steps of embodiments of the present disclosure, unless otherwise specified, should not be understood to limit an execution order.

What is claimed is:

1. A laser device comprising:
a laser device body and
a light-emission assembly arranged at one end of the laser device body and including:
an optical processing assembly including a first reflection layer, a gain medium layer, and a second reflection layer arranged in sequence;
wherein:
at least two metasurface devices are arranged in at least one of the first reflection layer or the second reflection layer; and
the at least two metasurface devices are configured to reflect or refract to-be-emitted light to cause the to-be-emitted light to be transmitted and modulated through the gain medium layer.

2. The laser device according to claim 1, wherein the optical processing assembly further includes:
a first metal electrode layer arranged at a first end of the light-emission assembly;
a second metal electrode layer arranged at a second end of the light-emission assembly;
an isolation layer arranged at an end of the second metal electrode layer; and
a substrate layer arranged at an end of the isolation layer.

3. The laser device according to claim 2, wherein the optical processing assembly further includes a light-emission opening structure arranged on a side of the first metal electrode layer.

4. The laser device according to claim 3, wherein one of the at least two metasurface devices is arranged on a side of at least one of the first reflection layer or the second reflection layer and corresponding to the light-emission opening structure.

5. The laser device according to claim 3, wherein one of the at least two metasurface devices is arranged in the first reflection layer and includes a semi-transparent and semi-reflective type metasurface device.

6. The laser device according to claim 3, wherein one of the at least two metasurface devices is arranged in the second reflection layer and includes a reflective type metasurface device.

7. The laser device according to claim 1, wherein one of the at least two metasurface devices includes one of a semi-transparent type and semi-reflective type metasurface device, a reflective type metasurface device, and a transmissive type metasurface device.

8. The laser device according to claim 7, wherein:
a first surface of the semi-transparent and semi-reflective type metasurface device includes a distributed Bragg reflector; and
a second surface of the semi-transparent and semi-reflective type metasurface device includes a nanostructure.

9. The laser device according to claim 1, wherein each of the at least two metasurface devices includes one of a semi-transparent type and semi-reflective type metasurface device, a reflective type metasurface device, and a transmissive type metasurface device.

10. The laser device according to claim 9, wherein:
a first surface of the semi-transparent and semi-reflective type metasurface device includes a distributed Bragg reflector; and
a second surface of the semi-transparent and semi-reflective type metasurface device includes a nanostructure.
